(19) United States
(12) Patent Application Publication
(10) Pub. No.: US 2012/0305891 A1
(43) Pub. Date: Dec. 6, 2012

(54) GRAPHENE CHANNEL TRANSISTORS AND METHOD FOR PRODUCING SAME

(76) Inventors: Osama M. Nayfeh, Adelphi, MD (US); Madan Dubey, South River, NJ (US)

(21) Appl. No.: 13/479,552

(22) Filed: May 24, 2012

Related U.S. Application Data
(60) Provisional application No. 61/493,050, filed on Jun. 3, 2011.

(51) Int. Cl. H01L 29/78; H01L 21/20; B82Y 40/00; B82Y 99/00

(52) U.S. Cl. 257/26; 438/479; 438/3; 257/E29.255; 257/E21.09; 977/734

(57) ABSTRACT

Embodiments of graphene channel transistors and methods for producing same are provided herein. In some embodiments, a graphene channel transistor may include a substrate a having a source region, a drain region, and a dielectric material disposed between the source and drain regions; a channel region comprising a graphene layer disposed atop the dielectric material and partially atop the source and drain regions; and a composite gate electrode comprising an insulator layer disposed atop the graphene layer and a conductive layer disposed atop the insulator layer.

This application claims the benefit of U.S. Provisional application No. 61/493,050 filed on Jun. 3, 2011.

### GOVERNMENT INTEREST

Governmental Interest—The invention described herein may be manufactured, used and licensed by or for the U.S. Government.

### FIELD OF INVENTION

Embodiments of the present invention generally relate to transistors, and more specifically, to graphene channel transistors and fabrication methods.

### BACKGROUND OF THE INVENTION

Current graphene transistors typically comprise a graphene film mounted on silicon oxide (SiO₂) with subsequently deposited metal contacts for the source and drain. Such designs suffer from numerous limitations in regard to their performance, functionalities, and scalabilities. In addition, the processing technology is not amenable to full-substrate development with extreme scalability.

Therefore, the inventors have provided improved graphene channel transistors and methods of producing same.

### BRIEF SUMMARY OF THE INVENTION

Embodiments of graphene channel transistors and methods for producing same are provided herein. In some embodiments, a graphene channel transistor may include a substrate a having a source region, a drain region, and a dielectric material disposed between the source and drain regions; a channel region comprising a graphene layer disposed atop the dielectric material and partially atop the source and drain regions; and a composite gate electrode comprising an insulator layer disposed atop the graphene layer and a conductive layer disposed atop the insulator layer.

In some embodiments, a graphene channel transistor may include a substrate comprising a silicon layer and a silicon oxide layer disposed atop the silicon layer, the substrate having a source region, a drain region, and a dielectric material disposed between the source and drain regions, wherein the source region, the drain region, and the dielectric material are disposed atop the silicon oxide (SiO₂) layer, wherein the dielectric material comprises one or more of a high-k dielectric material, a piezoelectric material, or a ferroelectric material, and wherein each of the source and drain regions include a first layer of silicon and a second layer of silicon germanium disposed atop the first layer of silicon; a channel region comprising a graphene layer disposed atop the dielectric material and partially atop the source and drain regions; and a composite gate electrode comprising an insulator layer disposed atop the graphene layer and a conductive layer disposed atop the insulator layer, wherein the insulator layer comprises one or more of a high-k dielectric material, a piezoelectric material, or a ferroelectric material, and wherein the conductive layer comprises one or more of gold, chrome, or platinum chrome.

In some embodiments, a method for fabricating a graphene channel transistor may include disposing a graphene layer atop a dielectric material and partially atop a source region and a drain region of a substrate to form a channel region; and forming a composite gate electrode atop the graphene layer, the composite gate electrode comprising an insulator layer disposed atop the graphene layer and a conductive layer disposed atop the insulator layer.

Other and further embodiments of the present invention are discussed below.

### BRIEF DESCRIPTION OF THE DRAWINGS

So that the manner in which the above recited features of the present invention can be understood in detail, a more particular description of the invention, briefly summarized above, can be made by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a graphene channel transistor in accordance with some embodiments of the present invention.

FIG. 2 depicts a flow chart of a method for fabricating a graphene channel transistor in accordance with some embodiments of the present invention.

FIGS. 3A-G respectively schematically depict the stages of fabrication of a graphene channel transistor in accordance with the method of FIG. 2.

### DETAILED DESCRIPTION OF THE INVENTION

Embodiments of graphene channel transistors and methods for producing same are provided herein. Embodiments of the present invention provide graphene based transistors, including hetero-junction transistors, that contain a graphene channel that may be interfaced heterogeneously to a semiconductor source and drain and insulators. Embodiments of the present invention also advantageously provide a manufacturing method for graphene channel transistors that can be performed with currently available equipment. Embodiments of the present invention also advantageously provide graphene channel transistors that include heterojunctions formed between graphene and group IV or III-V semiconductors that can form extremely scaled devices with varying functionality. For example, the versatility of the present invention allows for other uses or device designs based on the particular choice of material or heterojunction provided.

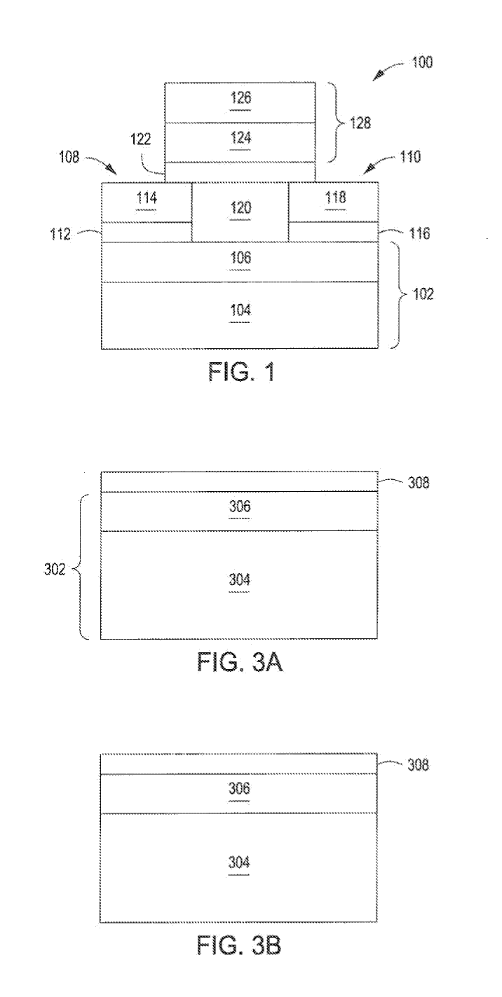

FIG. 1 depicts a graphene channel transistor 100 in accordance with some embodiments of the present invention. As depicted in FIG. 1, the graphene channel transistor 100 comprises a substrate 102 a having a source region 108, a drain region 110, and a dielectric material 120 disposed between the source and drain regions 108, 110. A channel region comprising a graphene layer 122 is disposed atop the dielectric material 120 and partially atop the source and drain regions 108, 110. A composite gate electrode 128 is disposed atop the graphene layer 122. The composite gate electrode 128 comprises an insulator layer 124 disposed atop the graphene layer 122 and a conductive layer 126 disposed atop the insulator layer 124.

The substrate 102 may comprise any suitable substrate for forming transistors thereupon. Non-limiting examples of suitable substrate include silicon substrates and silicon-on-insulator (SOI) substrates. For example, in some embodiments the substrate 102 further comprises a silicon layer 104 and a silicon oxide (SiO₂) layer 106 disposed atop the silicon layer 102. The source region 108, the drain region 110, and the dielectric material 120 may be disposed atop the silicon oxide (SiO₂) layer 106.

Each of the source and drain regions 108, 110 may include one or more layers. For example, in some embodiments, each of the source and drain regions 108, 110 may comprise a first layer 112,116 and a second layer 114,118, wherein the first layer 108, 110 is a different material than the second layer 114, 118. In some embodiments, the first layer 108, 110 may be silicon. In some embodiments the second layer 114, 118 may be silicon germanium (SiGe), gallium arsenide (GaAs), indium gallium arsenide (InGaAs), gallium nitride (GaN), aluminum gallium nitride (AlGaN), or the like. In one example, the first layer may be silicon and the second layer may be silicon germanium.

The dielectric material 120 may be any dielectric material suitable for forming the transistor 100. In some embodiments, the dielectric material 120 may comprise one or more of a high-k dielectric material, a piezoelectric material, or a ferroelectric material. As used herein, a high-k dielectric material is a material having a dielectric constant of greater than about 3.9. Examples of suitable materials for the dielectric material 120 include one or more of silicon oxide (SiO₂), silicon nitride (SiN), aluminum oxide (Al₂O₃), hafnium oxide (HfO₂), or the like.

In some embodiments, the graphene layer 122 may be a very thin layer, such as a monolayer or bilayer of graphene. The graphene layer 122 is disposed completely atop the dielectric material 120 and partially atop the source region 108 and the drain region 110. By providing the graphene layer 122 atop the source and drain regions 108, 110 and below the gate electrode 128, various advantages may be obtained. For example, in the transistor 100, graphene channels can be used in conjunction with appropriate source/drain material to enable unipolar or ambipolar devices depending on the selected semiconductor region. In addition, such interfacing can be used to allow for the mechanism of operation to be controlled, for example tunneling based or thermal based. Also, novel insulators can be used to take advantage of extremely large dielectric constants or novel functionalities such as based on ferroelectric or piezoelectric effects to provide for additional voltage gain to allow for extremely low voltage operation. In some embodiments, the heterogeneously interfaced source and drain regions may be formed of materials that produce novel hetero-junctions and functionalities. For example, the hetero-junctions of the transistor 100 allow for control of the carrier type and injection mechanism of transport. In addition, the selection of the dielectric material 120 that supports the graphene layer 122 may facilitate providing high quality attributes such as high mobility and voltage gain.

As discussed above, the composite gate electrode 128 comprises an insulator layer 124 disposed atop the graphene layer 122 and a conductive layer 126 disposed atop the insulator layer 124. In some embodiments, the insulator layer 124 comprises one or more of a high-k dielectric material, a piezoelectric material, or a ferroelectric material. In some embodiments, the conductive layer 126 comprises one or more of gold, chrome, or platinum chrome.

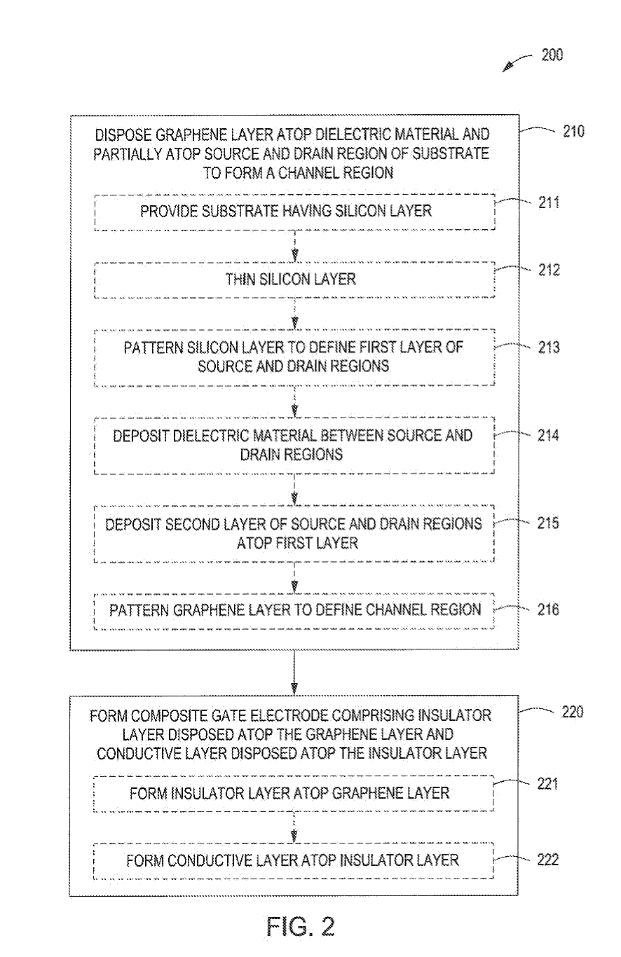

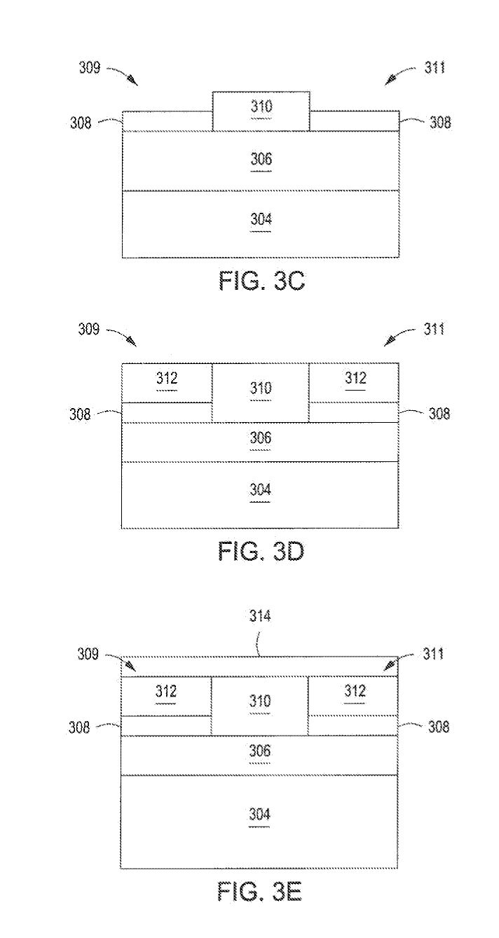

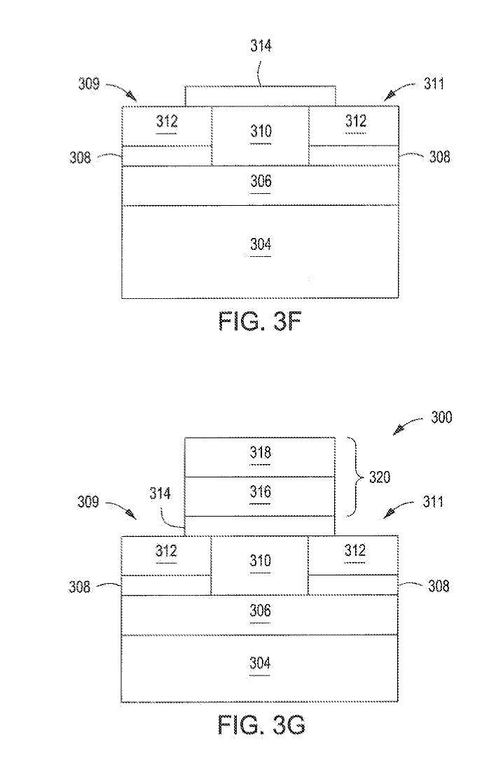

The transistor 100 described above may advantageously be fabricated in inventive methods that utilize conventional thin film substrate processing techniques. For example, FIG. 2 depicts a flow chart of a method 200 for fabricating a graphene channel transistor in accordance with some embodiments of the present invention. FIGS. 3A-G respectively schematically depict the stages of fabrication of a graphene channel transistor in accordance with the method of FIG. 2.

The method 200 generally begins at 210 where a graphene layer is disposed atop a dielectric material and partially atop a source region and a drain region of a substrate to form a channel region. In some embodiments, the substrate may be provided that already has the dielectric material and the source and drain regions formed thereon. Alternatively, the inventive methods may include forming the dielectric material and the source and drain regions on a substrate.

For example, in some embodiments, as shown at 211 and in FIG. 3A, a substrate 302 may be provided having a first layer of silicon 208 disposed on an upper surface of the substrate 302. The substrate 302 may be any suitable substrate as discussed above with respect to FIG. 1 and may include one or more layers. For example, in some embodiments, the substrate 302 may comprise a silicon on insulator substrate, such as a silicon layer 304 and a silicon oxide (SiO2) layer 306, wherein the first layer of silicon 308 is an active layer of silicon disposed on the silicon oxide (SiO2) layer 306.

Next, at 212, the first layer of silicon 308 may be thinned, as depicted in FIG. 3B. The first layer of silicon 308 may be thinned to any suitable thickness for the desired application. In some embodiments, the first layer of silicon 308 may be thinned to form an active film thickness of less than about 10 nm.

At 213, the thinned first layer of silicon 308 is patterned to define respective first layers of a source region 309 and a drain region 311, as depicted in FIG. 3C. For example, the thinned first layer of silicon 308 may be patterned and etched into islands or mesas corresponding to the source region 309 and the drain region 311.

At 214, a dielectric material 310 is deposited between the source and drain regions 309, 311, as also shown in FIG. 3C. The dielectric material 310 may be deposited by any suitable technique, such as by physical vapor deposition (PVD), atomic layer deposition (ALD), e-beam evaporation, chemical vapor deposition (CVD, or the like. The dielectric material 310 may comprise any suitable dielectric material, depending upon the application. In some embodiments, the dielectric material 310 may comprise one or more of a high-k dielectric material, a piezoelectric material, or a ferroelectric material.

At 215, a second layer 312 of the source and drain regions 309, 311 is deposited atop the respective first layers 308 of the source region 309 and the drain region 311, as shown in FIG. 3D. The second layer 312 may comprise any suitable materials for the application. In some embodiments, the second layer 312 may comprise one or more of silicon germanium (SiGe), gallium arsenide (GaAs), indium gallium arsenide (InGaAs), gallium nitride (GaN), or aluminum gallium nitride (AlGaN). The second layer 312 may be deposited by any suitable technique, such as, for example, a selective epitaxial CVD process wherein the second layer 312 is grown selectively atop the first layer 308.

As discussed above with respect to 210, a graphene layer 314 is disposed atop the dielectric material 310 and partially atop the source region 309 and the drain region 311 of the substrate to form a channel region, as shown in FIGS. 3E-F. For example, the graphene layer 314 may be initially disposed atop the substrate as shown in FIG. 3E, and subsequently patterned to the channel region as shown in FIG. 3F. Forming the source and drain components prior to the deposition of the graphene layer 314 advantageously minimizes the thermal budget that the graphene layer 314 is exposed to, which facilitates retaining higher purity and quality graphene layers. For example, if the interface between the graphene and adjacent components gets contaminated the device performance may suffer or fail. The present methods thus facilitate providing graphene channel transistors having improved performance and reliability.

In some embodiments, the graphene layer 314 may be formed on a transfer substrate and subsequently transferred from the transfer substrate to the substrate 302 using conventional techniques. In some embodiments, the upper surface of the substrate may be cleaned, such as by, wet or dry etching, prior to transferring the graphene layer 314 to the substrate 302. As shown at 216 and FIG. 3F, the graphene layer 314 may then be patterned such that the graphene layer 314 is disposed atop the dielectric material 308 and partially atop the source region 309 and the drain region 311 of the substrate (e.g., partially atop the second layer 312 of the source and drain regions 309, 311). In some embodiments, the layer of graphene may be a monolayer or a bilayer (e.g., may have a thickness of about one atom thick, or about two atoms thick, or less than about a few atoms thick).

Next, at 220, a. composite gate electrode 320 is disposed atop the graphene layer, as shown in FIG. 3G. The composite gate electrode 320 may comprise an insulator layer 316 disposed atop the graphene layer 314 and a conductive layer 318 disposed atop the insulator layer 316. The composite gate electrode 320 may be deposited and pattered using conventional techniques. For example, as shown at 221, the insulator layer 316 may be first disposed atop the graphene layer 314. In some embodiments, the insulator layer 316 comprises one or more of a high-k dielectric material, a piezoelectric material, or a ferroelectric material. Next, at 222, the conductive layer 318 is disposed atop the insulator layer 316. In some embodiments, the conductive layer 318 comprises one or more of gold, chrome, or platinum chrome.

Thus, graphene channel transistors and methods for fabricating the same have been provided. Embodiments of the inventive methods provide for a fabrication flow that utilizes current infrastructure to produce graphene channel transistors that may provide for extremely scaled structures. As the process flow may utilize existing manufacturing infrastructure and tools, the cost of fabrication may be advantageously minimized. In addition, as the source/drain components are produced prior to the deposition of the graphene channel, the thermal budget that the graphene channel is exposed to during subsequent processing is advantageously minimized.

In some embodiments, the inventive transistors contain heterogeneously interfaced source/drain regions which may be formed of materials that produce desired heterojunctions and functionalities. For example, graphene channels can be used in conjunction with appropriate source/drain material to enable unipolar or ambipolar devices depending on the selected semiconductor region. In addition, such interfacing can be used to allow for the mechanism of operation to be controlled, for example tunneling based or thermal based.

In some embodiments, the inventive methods facilitate producing a graphene channel transistor where the graphene is in intimate contact with novel insulators/substrates that could provide for improved/novel functionalities. For example, insulators can be used to take advantage of extremely large dielectric constants or functionalities such as based on ferroelectric or piezoelectric effects to provide for additional voltage gain to allow for extremely low voltage operation.

While the foregoing is directed to embodiments of the present invention, other and further embodiments of the invention may be devised without departing from the basic scope thereof.

1. A graphene channel transistor, comprising:
a substrate a having a source region, a drain region, and a dielectric material disposed between the source and drain regions;
a channel region comprising a graphene layer disposed atop the dielectric material and partially atop the source and drain regions; and
a composite gate electrode comprising an insulator layer disposed atop the graphene layer and a conductive layer disposed atop the insulator layer.

2. The transistor of claim 1, wherein the substrate further comprises a silicon layer and a silicon oxide (SiO₂) layer disposed atop the silicon layer, wherein the source region, the drain region, and the dielectric material are disposed atop the silicon oxide (SiO₂) layer.

3. The transistor of claim 1, wherein each of the source and drain regions include one or more layers comprising one or more of silicon (Si), silicon germanium (SiGe), gallium arsenide (GaAs), indium gallium arsenide (InGaAs), gallium nitride (GaN), or aluminum gallium nitride (AlGaN).

4. The transistor of claim 3, wherein each of the source and drain regions include a first layer of silicon and a second layer of silicon germanium disposed atop the first layer of silicon.

5. The transistor of claim 1, wherein the dielectric material comprises one or more of a high-k dielectric material, a piezoelectric material, or a ferroelectric material.

6. The transistor of claim 1, wherein the graphene layer comprises a monolayer or bilayer of graphene.

7. The transistor of claim 1, wherein the insulator layer comprises one or more of a high-k dielectric material, a piezoelectric material, or a ferroelectric material.

8. The transistor of claim 1, wherein the conductive layer comprises one or more of gold, chrome, or platinum chrome.

9. A graphene channel transistor, comprising:
a substrate comprising a silicon layer and a silicon oxide layer disposed atop the silicon layer, the substrate having a source region, a drain region, and a dielectric material disposed between the source and drain regions, wherein the source region, the drain region, and the dielectric material are disposed atop the silicon oxide (SiO₂) layer, wherein the dielectric material comprises one or more of a high-k dielectric material, a piezoelectric material, or a ferroelectric material, and wherein each of the source and drain regions include a first layer of silicon and a second layer of silicon germanium disposed atop the first layer of silicon;
a channel region comprising a graphene layer disposed atop the dielectric material and partially atop the source and drain regions; and
a composite gate electrode comprising an insulator layer disposed atop the graphene layer and a conductive layer disposed atop the insulator layer, wherein the insulator layer comprises one or more of a high-k dielectric material, a piezoelectric material, or a ferroelectric material, and wherein the conductive layer comprises one or more of gold, chrome, or platinum chrome.

10. A method for fabricating a graphene channel transistor, comprising:
disposing a graphene layer atop a dielectric material and partially atop a source region and a drain region of a substrate to form a channel region; and
forming a composite gate electrode atop the graphene layer, the composite gate electrode comprising an insulator layer disposed atop the graphene layer and a conductive layer disposed atop the insulator layer.

11. The method of claim 10, further comprising:
providing a substrate comprising a first layer of silicon disposed on an upper surface of the substrate;
thinning the first layer of silicon; and
patterning the first layer of silicon to define respective first layers of a source region and a drain region.

12. The method of claim 11, wherein the substrate further comprises:
a silicon layer; and
a silicon oxide (SiO₂) layer, wherein the first layer of silicon is disposed on the silicon oxide (SiO₂) layer.

13. The method of claim 11, further comprising:
depositing a dielectric material between the source and drain regions.

14. The method of claim 13, wherein the dielectric material comprises one or more of a high-k dielectric material, a piezoelectric material, or a ferroelectric material.

15. The method of claim 13, further comprising:
depositing a second layer of the source and drain regions atop the respective first layers of the source region and the drain region.

16. The method of claim 15, wherein the second layer of the source and drain regions comprises one or more of silicon germanium (SiGe), gallium arsenide (GaAs), indium gallium arsenide (InGaAs), gallium nitride (GaN), or aluminum gallium nitride (AlGaN).

17. The method of claim 15, further comprising:
forming the graphene layer on a transfer substrate and subsequently transferring the graphene layer from the transfer substrate to the substrate; and
patterning the graphene layer such that the graphene layer is disposed atop the dielectric material and partially atop the source region and the drain region of the substrate.

18. The method of claim 10, further comprising:
forming the graphene layer on a transfer substrate and subsequently transferring the graphene layer from the transfer substrate to the substrate; and
patterning the graphene layer such that the graphene layer is disposed atop the dielectric material and partially atop the source region and the drain region of the substrate.

19. The method of claim 10, wherein the insulator layer comprises one or more of a high-k dielectric material, a piezoelectric material, or a ferroelectric material.

20. The method of claim 10, wherein the conductive layer comprises one or more of gold, chrome, or platinum chrome.
